(19) United States
(12) Patent Application Publication
(10) Pub. No.: US 2007/0202615 A1
(43) Pub. Date: Aug. 30, 2007

(54) Method of measuring critical dimension

(76) Inventors: Byung-Sug Lee, Gyeonggi-do (KR); Mi-Sung Lee, Seoul (KR); Yu-Sin Yang, Seoul (KR); Yun-Jung Jee, Gyeonggi-do (KR); Chung-Sam Jun, Gyeonggi-do (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/702,599

(22) Filed: Feb. 6, 2007

(30) Foreign Application Priority Data
Feb. 14, 2006 (KR) 10-2006-0013961

(51) Int. Cl. H01L 21/66; G01R 31/26

(52) U.S. Cl. 438/14

(57) ABSTRACT

In a method of measuring a critical dimension for conductive structures or openings exposing conductive structures formed on a substrate, a corona ion charge is deposited on the conductive structures and/or an insulating layer having the openings in a measurement region of the substrate. The critical dimension of the conductive structures or the openings may be determined by comparing variations of a surface voltage caused by leakage current through the conductive structures with reference data to thereby improve reliability of the critical dimension measurement.

### BACKGROUND OF THE INVENTION

1. Field of the Invention

The present invention relates to a method of measuring a critical dimension. More particularly, the present invention relates to a method of measuring a critical dimension of conductive structures or openings exposing conductive structures formed on a semiconductor substrate.

This application claims priority under 35 USC § 119 to Korean Patent Application No. 10-2006-0013961 filed on Feb. 14, 2006, the subject matter of which is hereby incorporated by reference in its entirety.

2. Description of the Related Art

Electronic circuits are formed on a semiconductor substrate, such as a silicon wafer, through the application of a complex sequence of fabrication processes. Such fabrication processes include; material layer formation processes, photolithography processes, etching processes, ion implantation processes, planarization processes, inspection processes, cleaning processes, etc. Indeed, many of the individually applied fabrication processes are repeated numerous times during the manufacture of contemporary semiconductor devices.

Various material layer formation processes are used to selectively form one or more layers on the working surface of the semiconductor substrate. These material layers may then be very finely patterned through the use of etching processes to form desired structures. Further, selective ion implantation processes may be used to alter or define the electrical properties of material layers or portions of material layers. For example, impurity regions may be formed in one or more material layers. These impurity regions may serve as source/drain regions in constituent transistors. Subsequent material layer formation and etching processes are then used to connect the source/drain regions to conductive structures serving as bit lines, storage electrodes, contact pads and/or contact plugs.

The precision required in the foregoing processes is daunting. Even minute errors in a single formation, patterning, implantation and cleaning process may result in complete failure of the semiconductor device. Thus, inspection processes are critical to the successful manufacture of these devices. Various types of inspection processes are repeatedly applied during the manufacture of semiconductor devices. Most inspection processes are directed to one or more “critical dimension(s)” (e.g., geometric height, width, depth, length, separation, aspect ratio, area, etc.).

For example, critical dimension(s) of various structures formed on the semiconductor substrate may be measured using an electron microscope. More particularly, the image of a measurement region defined on a semiconductor substrate may be acquired using a scanning electron microscope (SEM) or a transmission electron microscope (TEM). With acquisition of the region's image, certain critical dimensions may be determined and analyzed.

Conventionally, the determination and analysis of critical dimensions has been done on a sampled basis. That is, one or several critical dimensions from selected structures in a measurement region are determined (e.g., measured) and taken as being exemplary of all similar critical dimensions from all other structures. However, with increasing integration densities, more numerous structures, and ever more stringent critical dimension tolerances, such an approach is proving increasingly less reliable.

An improved approach to the determination and analysis of critical dimensions is need. Such an approach would measure critical dimensions for many more (and possibly all) structures in a defined measurement region. Thereafter, an accurate average value for the measured critical dimension may be obtained. This larger average value dramatically increases the accuracy of the inspection process.

### SUMMARY OF THE INVENTION

In one embodiment, the invention provides, a method of measuring a critical dimension associated with conductive structures, the method comprising; depositing a corona ion charge on a substrate including conductive structures, measuring surface voltage variations caused by leakage current related to the conductive structures, and comparing the measured surface voltage variations with reference data to determine the critical dimension.

In another embodiment, the invention provides a method of measuring a critical dimension associated with openings formed in an insulating layer, the method comprising; depositing a corona ion charge on the insulating layer, wherein the insulating layer is formed on a substrate and exposes conductive structures formed on the substrate, measuring surface voltage variations caused by leakage current related to the exposed conductive structures, and comparing the measured surface voltage variations with reference data to determine the critical dimension.

### BRIEF DESCRIPTION OF THE DRAWINGS

Figure (FIG.) 1 is a flow chart summarizing a method of measuring a critical dimension in accordance with an embodiment of the invention;

FIG. 2 is a flow chart summarizing a method of obtaining reference data used in a method of measuring a critical dimension in accordance with an embodiment of the invention;

FIGS. 3 and 4 are graphs showing relationships between a critical dimension associated with direct contact holes formed on a substrate and a surface voltage;

FIG. 5 is a graph showing relationships between a critical dimension associated with storage electrodes formed on a substrate and a surface voltage;

FIG. 6 is a schematic view illustrating a measurement apparatus for performing a method of measuring a critical dimension in accordance with an embodiment of the invention;

FIG. 7 is an enlarged front view illustrating a corona charger and a measurement probe unit as shown in FIG. 6; and

FIG. 8 is a plan view illustrating a measurement apparatus as shown in FIG. 6.

### DESCRIPTION OF EMBODIMENTS

Embodiments of the invention now will be described with reference to the accompanying drawings. The invention may, however, be embodied in many different forms and should not be construed as being limited to the embodiments set forth herein. Rather, these embodiments are presented as teaching examples. Throughout the written description and drawings, like reference numerals refer to like or similar elements.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element's as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

FIG. 1 is a flow chart summarizing a method of measuring a critical dimension in accordance with an embodiment of the invention. Referring to FIG. 1, the method first includes depositing a corona ion charge on a substrate (S100), the substrate having conductive structures previously formed thereon.

In one embodiment of the invention, the conductive structures include transistors formed from word lines, and first and second impurity regions. The first and second impurity regions (acting as source/drain regions) are formed in selected portions of the substrate working surface adjacent to the word lines. Further, the transistors are associated with a first insulating layer formed on the substrate, and first openings formed through the first insulating layer to expose the first and second impurity regions.

In the context of this embodiment, the corona ion charge may be deposited on the first insulating layer and on the first and second impurity regions exposed through the first openings.

In another related embodiment of the invention, the conductive structures include first and second contact pads formed on the substrate. The first and second contact pads may be formed in the first openings to electrically connect the first and second impurity regions. In the context of this embodiment, the corona ion charge is deposited on the first insulating layer and the first and second contact pads.

In still another related embodiment of the invention, a second insulating layer is formed on the first insulating layer and the first and second contact pads. Second openings are formed through the second insulating layer to expose the first contact pads formed in connection with the first impurity regions. That is, a second insulating layer having direct contact holes is formed on the first insulating layer. In the context of this embodiment, the corona ion charge is deposited on the second insulating layer and the exposed first contact pads.

In still another related embodiment of the invention, direct contact plugs are formed in the second opening to electrically connect the bit lines subsequently formed on the second insulating layer and the first contact pads. In the context of this embodiment, the corona ion charge is deposited on the direct contact plugs and the second insulating layer.

In still another related embodiment of the invention, a third insulating layer is formed on the bit lines and the second insulating layer. Third openings are formed through the second and third insulating layers to expose the second contact pads. In the context of this embodiment, the corona ion charge is deposited on the third insulating layer and the second contact pads exposed by the third openings.

In still another related embodiment of the invention, buried contact plugs are formed in the third openings to electrically connect the second contact pads and storage electrodes subsequently formed on the third insulating layer. In the context of this embodiment, the corona ion charge is deposited on the third insulating layer and the buried contact plugs.

In still another related embodiment of the invention, a fourth insulating layer or a molding layer is formed on the third insulating layer and the buried contact plugs. The fourth insulating layer includes fourth openings exposing the buried contact plugs to form storage electrodes. In the context of this embodiment, the corona ion charge is deposited on the fourth insulating layer and the buried contact plugs exposed by the fourth openings.

In still another related embodiment of the invention, storage electrodes are formed in the fourth openings, and the corona ion charge is deposited on the storage electrodes and the fourth insulating layer.

In still another related embodiment of the invention, the corona ion charge is deposited on the third insulating layer and the storage electrodes after removing the fourth insulating layer.

Thus, the corona ion charge may be deposited on any one or more of a number of predetermined measurement regions on the substrate. For example, a plurality of measurement regions may be defined on the substrate before fabrication begins, and the corona ion charge may be deposited on any one of these regions at any point in the fabrication of the semiconductor device (i.e., following any process in the fabrication sequence). In one embodiment drawn to contemporary examples, each of measurement regions has a diameter ranging from a few micrometers to several hundreds of micrometers. In one specific embodiment, a measurement region has a diameter of about 20 micrometers.

Following deposition of the corona ion charge, variations in surface voltage caused by leakage current associated with the conductive structures is measured (S110). Such leakage currents occur as corona ions are neutralized via the conductive structures.

The measured variations in surface voltage may be determined in relation to the actual surface area of the conductive structures. For example, any variation from specification in the formation of storage electrodes will cause a variation in an expected surface voltage associated with the defined surface area of the storage electrodes. One or more critical dimensions for the actual storage electrodes formed on the substrate may be determined in relation to the variation in the measured surface voltage. This is also true of other conductive structures including impurity regions, contact pads, contact plugs, etc. That is, departures from defined conductive structure geometry will result in measurable variations in the surface voltage associated with the conductive structure. Both conductive structures formed on a material layer and those exposed through a material layer may be measured in this manner. Critical dimensions for conductive structures as well as openings in material layers may be determined in this manner (S120).

In one embodiment of the invention, actual critical dimensions may be determined by comparing a corresponding surface voltage variation to reference data for an ideal or reference (i.e., meeting design specifications) conductive structure or opening having the sought after critical dimension.

Given the fact that the corona ion change is potentially formed over many conductive structures, the critical dimension determined by the foregoing approach will be substantially an average value for the measured critical dimension. Thus, the reliability of the critical dimension measurement is improved. Further, the critical dimension measurement process may be performed in a measurement region having a relatively wide area, and thus the reliability of the critical dimension measurement may be further improved.

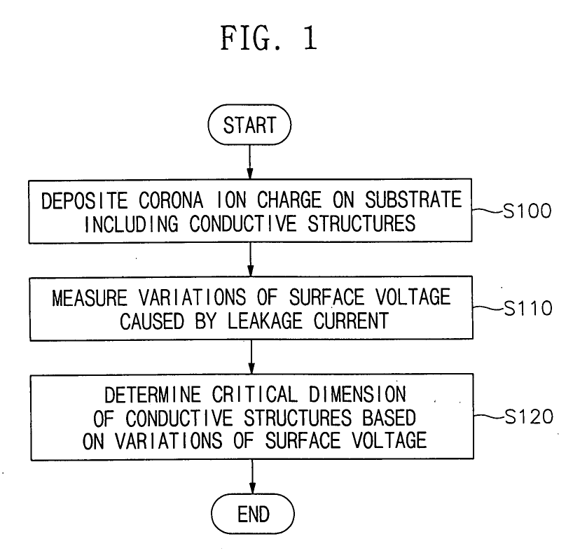

FIG. 2 is a flow chart illustrating a method of obtaining reference data used in a method of measuring a critical dimension in accordance with an embodiment of the invention.

Referring to FIG. 2, reference critical dimensions for a reference conductive structure (or opening exposing the reference conductive structure) is measured from a reference substrate (S10). The reference substrate may be substantially the same as the target substrate, but has typically been vetted and is known to be good in the context of the current design. In one embodiment of the invention, an average value for the measured reference critical dimensions may be calculated.

For example, impurity regions used as source/drain regions may be formed in selected surface portions of the reference substrate. Further, conductive structures such as contact pads, contact plugs, storage electrodes, etc., may be formed on the reference substrate, and an insulating layer having openings exposing the conductive structures may be formed on the conductive structures.

Certain reference critical dimensions associated with any one or more of these conductive structures may be measured using an image acquired by an electron microscope, such as a scanning electron microscope (SEM).

Thereafter, a corona ion charge is deposited on the reference conductive structures (S12). That is, the corona ion charge is deposited on a measurement region of the reference substrate. The measurement region of the reference substrate may have a diameter similar to that of a target substrate to be measured, per the above.

Thereafter, variations in a reference surface voltage caused by leakage current associated with the reference conductive structures is measured (S14).

Then, the reference data is obtained based on the measured reference critical dimensions and the measured variations of the reference surface voltage. Particularly, the reference data may include an average value of the critical dimensions of the conductive structures or the opening measured in the measurement region of the reference substrate, and the variations of surface voltage corresponding thereto.

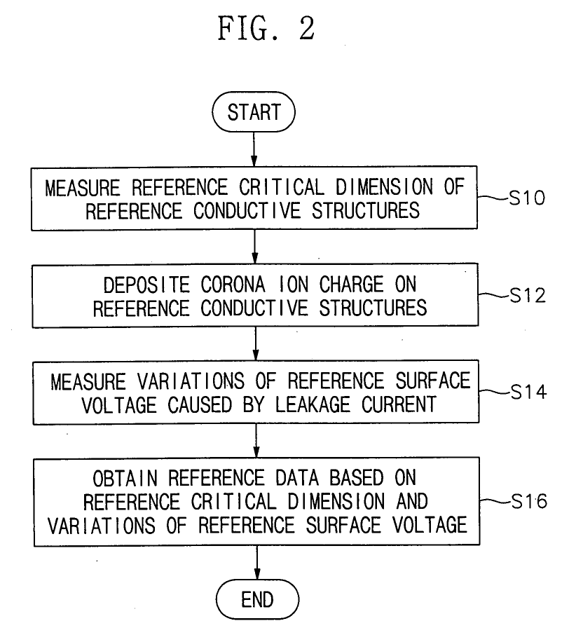

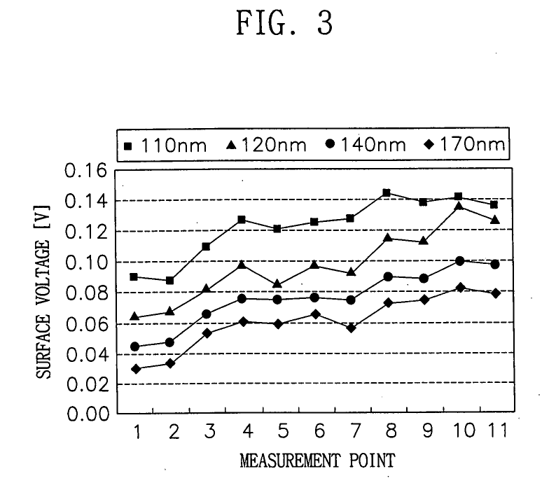

FIGS. 3 and 4 are graphs showing relationships between a critical dimension associated with direct contact holes formed on a substrate and a surface voltage.

To obtain this data, contact pads were formed on a first reference substrate. Then a first insulating layer having first direct contact holes exposing the contact pads was formed on the first reference substrate. The first direct contact holes had a critical dimension of about 110 nanometers.

Further, a second, third and fourth reference substrate were similarly prepared, but respective second, third and fourth direct contact holes had critical dimensions of about 120 nanometers, 140 nanometers, and 170 nanometers.

Corona ion charges were deposited on measurement regions of the first, second, third and fourth reference substrates. After an hour, surface voltages were measured at various points within the measurement regions. Variations in the surface voltage over time were also measured in the measurement regions.

As the critical dimension of the direct contact holes increased, a lower measured surface voltage was measured, as shown in FIGS. 3 and 4.

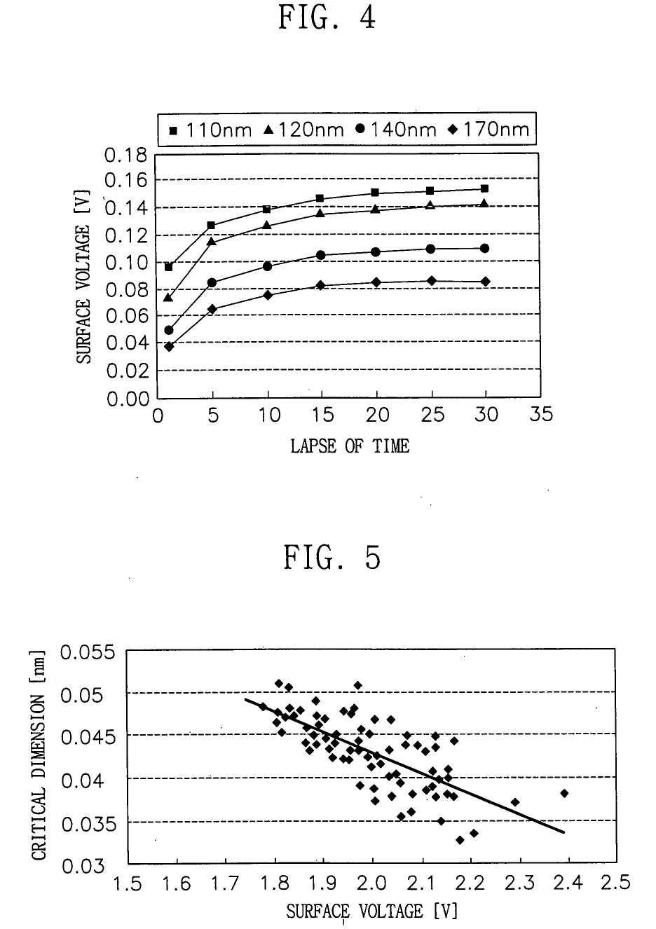

FIG. 5 is a graph showing relationships between a critical dimension for storage electrodes formed on a substrate and a surface voltage.

A plurality of five reference substrates including storage electrodes was prepared. Critical dimensions for the storage electrodes were measured in measurement regions of the five reference substrates using an SEM. Further, corona ion charges were deposited on the five reference substrates, and surface voltages were measured in the measurement regions after an hour. As may be seen from FIG. 5, the surface voltages were reduced as the critical dimension of the storage electrodes increased.

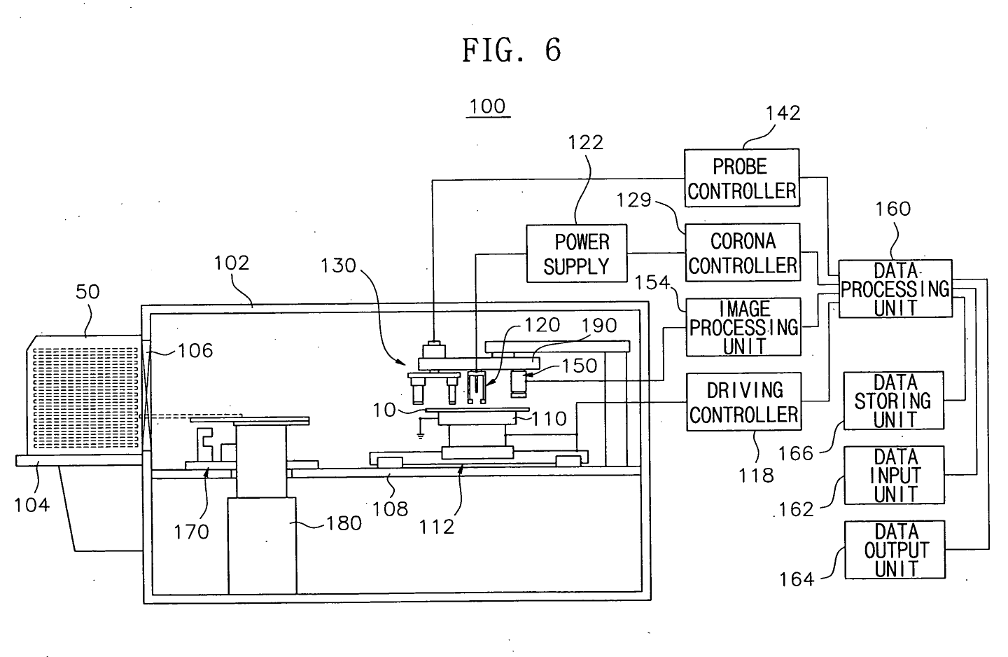

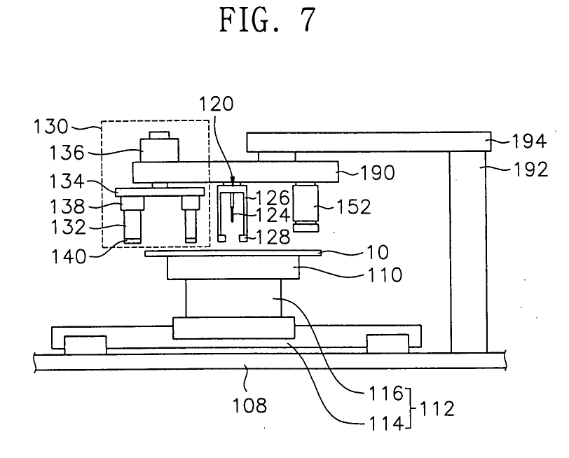

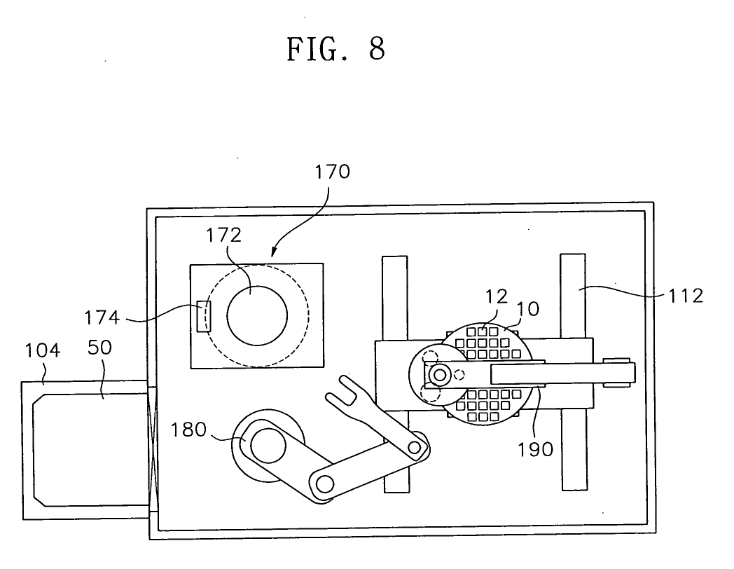

FIG. 6 is a schematic view illustrating a measurement apparatus adapted to perform a method of measuring a critical dimension in accordance with an embodiment of the invention. FIG. 7 is an enlarged front view of the corona charger and a measurement probe unit of FIG. 6. FIG. 8 is a plan view of the measurement apparatus shown in FIG. 6.

Referring collectively to FIGS. 6, 7, and 8, a measurement apparatus 100 includes a measurement chamber 102, a stage 110 supporting a semiconductor substrate 10, (e.g., a silicon wafer), a driving unit 112 moving stage 110, a corona charger 120 generating the corona ion charge deposited on semiconductor substrate 10, a probe unit 130 measuring surface voltage related to leakage current associated with conductive structures formed on semiconductor substrate 10. Measurement apparatus 100 also includes an image acquisition unit 150 acquiring an image of semiconductor substrate 10, a data processing unit 160 determining a critical dimension for the conductive structures (or related openings exposing the conductive structures) based on the measured surface voltage, a pre-aligning unit 170 pre-aligning semiconductor substrate 10, and a transfer robot 180 transferring semiconductor substrate 10 to/from measurement apparatus 100.

In the illustrated embodiment, measurement chamber 102 includes a support plate 104 extending from a sidewall of measurement chamber 102 to support a vessel 50 adapted to receive one or more semiconductor substrate(s) 10. A door 106 is provided in measurement chamber 102 through which semiconductor substrate 10 may pass. A base plate 108 is horizontally disposed in measurement chamber 102.

A driving unit 112 is arranged over base plate 108 and connected to a lower portion of stage 110 in order to move stage 110 horizontally and vertically. Driving unit 112 is connected to driving controller 118 via a signal line. In the illustrated embodiment, driving unit 112 is assumed to include a first driver 114 moving stage 110 in a horizontal direction, and a second driver 116 moving stage 110 in a vertical direction. First driver 114 may be a perpendicular coordinate type robot, and the second driver 116 may be a hydraulic or pneumatic cylinder.

In the illustrated embodiment, stage 110 is assumed to be connected to ground and adapted to hold semiconductor substrate 10 using a vacuum. With this configuration, semiconductor substrate 10 may be electrically grounded through stage 110.

Supporter 190 is disposed over stage 100 to support corona charger 120, probe unit 130 and image acquisition unit 150. As shown in the illustrated example, supporter 190 may be supported by a vertical arm 192 fixed to base plate 102 and a horizontal arm 194 extending from an upper portion of vertical arm 192.

Corona charger 120 includes a corona emitter 124 connected to a high voltage power supply 122, a housing 126 receiving corona emitter 124, and a corona-confining ring 128 mounted on a lower portion of housing 126. Corona-confining ring 128 surrounds and thereby confines a measurement region on semiconductor substrate 10 in which the corona ion charge is deposited. In one embodiment, corona emitter 124 comprises a tungsten carbide needle and corona-confining ring 128 is a metal ring. A high voltage of about ±8,000V is applied to corona emitter 124 by power supply 122. Corona-confining ring 128 is electrically connected to ground, and has an inner diameter ranging between about hundreds of micrometers to several millimeters. However, corona-confining ring 128 may be varied in its size and configuration in accordance with the size of the measurement region.

Positive or negative corona ion charges generated by corona emitter 124 are deposited on the measurement region of semiconductor substrate 10. This region is aligned under corona charger 120 through corona-confining ring 128. Driving unit 112 moves stage 110 to align each measurement region of semiconductor substrate 10 under corona charger 120. As the corona ion charge is deposited on the conductive structures (and/or an associated insulating layer) in a selected measurement region, corona-confining ring 128 is spaced apart from the conductive structures (and/or insulating layer) by a predetermined separation distance, (e.g., about 10 mils). Corona charger 120 and power supply 122 are controlled by a corona controller 129.

Probe unit 130 is disposed over semiconductor substrate 10 and is able to measure voltage variations between the bulk silicon of semiconductor substrate 10 and conductive structures (and/or an insulating layer associated with the conductive structures). In the illustrated example, probe unit 130 includes a plurality of measurement probes 132 having different sizes, a circular disk 134 supporting the probes 132, and a rotary driver 136 rotating the circular disk 134. Circular disk 134 is disposed under supporter 190, and rotary driver 136 is disposed on supporter 190. A rotary driving shaft connects rotary driver 136 with circular disk 134 through supporter 190.

One example of an acceptable measurement probe is the Kelvin probe, well known in the art. Each measurement probe 132 typically includes a capacitive pick-up plate 140 connected to a vibrator 138 and adapted to sense an electrical potential on semiconductor substrate 10. One or more vibrator(s) 138 is disposed around the lower surface of circular disk 134 with respect to a central axis of circular disk 134. Respective pick-up plates 140 may have different sizes. For example, probe unit 130 may include a plurality of probes corresponding to various measurement region sizes.

When surface voltage variations caused by leakage current associated with the conductive structures are measured using a selected measurement probe 132, the selected probe 132 is arranged across an air gap of about 5 mils from the measurement region.

Vibration of pick-up plate 140 with respect to the surface(s) of the measure region (containing conductive structures and/or an associated insulating layer) induces a time-varying current on a surface of pick-up plate 140. This time-varying current is proportional to a voltage potential difference between pick-up plate 140 and the conductive structures and/or associated insulating layer. The time-varying current generates a voltage substantially similar to a surface voltage potential on the surface(s) of the conductive structures and/or the associated insulating layer with respect to semiconductor substrate 10.

Selected measurement probes 132, vibrators 138 and rotary driver 136 may be connected to a probe controller 142 via signal lines. Probe controller 142 selects one among probes 132 in accordance with the size of the region to be measured. Probe controller 142 controls an operation of rotary driver 136 to locate a selected probe at a position adjacent to corona charger 120. Probe controller 142 also adjusts a vibration frequency for the selected probe. The time-varying current varies in accordance with the leakage current through the target conductive structures. Probe controller 142 measures the variations of the surface voltage in accordance with variations of the time-varying current.

In the illustrated example, image acquisition unit 150 is supported by supporter 190 and is adapted to acquire the image of semiconductor substrate 10 on stage 110. In one embodiment, image-obtaining unit 150 includes an imager 152 outputting an image of semiconductor substrate 10 to an image processor 154 creating the image data by processing the image of semiconductor substrate 10. Imager 152 may be implemented using any competent conventional device, (e.g., an optical microscope, a charge coupled device (CCD) camera, etc.).

Driving unit 112 moves stage 110 using the acquired image data to align a selected measurement region under corona charger 120 or selected measurement probe 132.

As shown in FIGS. 6-8, although apparatus 100 is shown with one corona charger 120 supported by supporter 190, it may include additional corona charging unit(s) having a similar configuration to that of probe unit 130. For example, the corona charging unit may include a second circular disk, a second rotary driver for rotating the second circular disk, and a plurality of corona chargers disposed in a circumferential direction on a lower surface of the second circular disk. The corona chargers may include corona-confining rings having different inside diameters, respectively, and may be selectively used in accordance with the size of the measurement region.

Pre-aligning unit 170 preliminarily aligns semiconductor substrate 10 and is arranged on base plate 108. Pre-alignment occurs upon transfer of semiconductor substrate 10 via transfer robot 180 and may be in relation to a flat zone or notch commonly provide in semiconductor substrate 10. As illustrated, pre-aligning unit 170 includes a rotary chuck 172 holding and rotating semiconductor substrate 10, an edge sensor 174 sensing the flat zone or notch, and an alignment controller (not shown) controlling operation of rotary chuck 172 in accordance with a signal from edge sensor 174.

Transfer robot 180 is adapted to transfer semiconductor substrate 10 and, as illustrated, is arranged in a direction substantially perpendicular to base plate 108. That is, transfer robot 180 extends in an upward direction through base plate 108. Transfer robot 180 transfers semiconductor substrate 10 from vessel 50 to pre-aligning unit 170. Transfer robot 180 then transfers the pre-aligned semiconductor substrate 10 onto stage 110. After the critical dimension measurement is completed, transfer robot 180 again transfers semiconductor substrate 10 to vessel 50.

Data processing unit 160 is connected to driving controller 118, corona controller 129, probe controller 142, and image processor 154. Data processing unit 160 compares the measured variation related surface voltage to reference data in order to determine the critical dimension of the conductive structures or associated insulating layer. In one embodiment, data processing unit 160 is further connected to a data-input unit 162, a data output unit 164, and a data storing unit 166.

Data-input unit 162 inputs data such as an amount of the corona ion charge to be deposited on the measurement region, positions of the measurement regions, sizes of the measurement regions, etc., into data-processing unit 160. Data-output unit 164 outputs the reference data, the measured variations of the surface voltage, the determined critical dimension, etc. Data-output unit 164 may be implemented using any number of conventional devices, (e.g., a monitor, a printer, a plotter, etc.). The reference data, the measured variations of the surface voltage, the determined critical dimension, etc., may be stored in data-storing unit 166.

Hereinafter, a method of measuring a critical dimension of conductive structures or associated openings of an insulating layer exposing the conductive structures using apparatus 100 as shown in FIGS. 6-8 will be explained in some additional detail.

Semiconductor substrate 10 is transferred from vessel 50 to pre-aligning unit 170, and then pre-aligned based on a constituent flat zone. More particularly, semiconductor substrate 10 is transferred to rotary chuck 172 of pre-aligning unit 170 by transfer robot 180 and then pre-aligned in accordance with a signal provided by edge sensor 174.

Pre-aligned semiconductor substrate 10 is loaded onto stage 110. Once loaded onto stage 110, semiconductor substrate 10 is held in place on an upper surface of stage 110 by vacuum pressure, thereby grounding semiconductor substrate 10.

Image data for semiconductor substrate 10 loaded on stage 110 is then obtained. Driving controller 118 controls driving unit 112 to properly place semiconductor substrate 10 under image acquisition unit 150. Imager 152 acquires image data for semiconductor substrate 10, and image processor 154 processes the image data to produce corresponding data provided to data processing unit 160.

A measurement recipe is input to data processing unit 160 by data input unit 162. The measurement recipe includes the amount of corona ion charge to be deposited on the measurement region, as well as the position(s) and size(s) of the measurement regions, etc.

A measurement region is arranged under corona charger 120. That is, driving unit 112 moves stage 110 so that corona charger 120 is arranged over the semiconductor substrate 10. Data processing unit 160 selects a measurement region in accordance with the measurement recipe, and transmits information such as position and related image data to driving controller 118. Driving controller 118 controls the operation of driving unit 112 in accordance with the position and image data so as to dispose the selected measurement region under corona charger 120 and adjust the air gap between corona charger 120 and the selected measurement region.

The corona ion charge is deposited onto the selected measurement region. That is, corona controller 129 controls the operation of corona charger 120 in accordance with the measurement recipe transmitted from data processing unit 160, such that the corona ion charge is deposited on the selected measurement region. Further, corona controller 129 controls the operation of power supply 122 connected to corona emitter 124 in order to adjust the amount of the corona ion charge deposited on the measurement region.

The selected measurement region is next positioned under probe unit 130. Probe controller 142 selects a measurement probe 132 in accordance with the size of the measurement region, and operates rotary driver 136 so that the selected probe 132 is disposed adjacent to corona charger 120. Driving controller 118 controls the operation of driving unit 112 using the image data transmitted from data processing unit 160 to align the selected measurement probe over the selected measurement region.

Variations of a surface voltage of selected measurement region are measured for a predetermined time. The surface voltage variations are measured by the selected probe 132 and probe controller 142. Particularly, probe controller 142 adjusts a vibration frequency of the selected probe 132, and measures the variations induced by the surface voltage by converting a time-varying current provided by the selected probe 132 into a corresponding surface voltage. The measured surface voltage variations are transmitted to data processing unit 160.

The measured surface voltage variations are analyzed to determine the critical dimension of the conductive structures and/or the openings in an associated insulating layer within the selected measurement region. Data processing unit 160 compares the measured surface voltage variations with the reference data stored in data storing unit 166 to determine the critical dimension of the conductive structures or the openings of the insulating layer.

Data output unit 164 outputs the determined critical dimension of the conductive structures or the openings. Data output unit 164 may also output the measured surface voltage variations and the reference data. The determined critical dimension, the surface voltage variations and the reference data may be displayed by a monitor, and/or may be output to a printer or plotter. Further, the determined critical dimension and surface voltage variations may be stored in data storing unit 166.

The critical dimension measurements for the remaining measurement regions may be similarly obtained, after which semiconductor substrate 10 is unloaded from stage 110.

In accordance with the foregoing embodiments of the invention, a critical dimension for conductive structures and/or openings in an associated insulating layer exposing the conductive structures in a measurement region may be determined on the basis of surface voltage variations caused by leakage current related to the conductive structures. The averaged critical dimension value thus obtained is much more accurate than the sampled values conventionally obtained.

Although certain embodiments of the present invention have been described above, it is understood that the invention is not be limited to only these example embodiments. Indeed, various changes and modifications to the foregoing may be made without removing such from the scope of the invention as defined by the following claims.

What is claimed is:

1. A method of measuring a critical dimension associated with conductive structures, the method comprising:
depositing a corona ion charge on a substrate including conductive structures;
measuring surface voltage variations caused by leakage current related to the conductive structures; and
comparing the measured surface voltage variations with reference data to determine the critical dimension.

2. The method of claim 1, wherein the conductive structures comprise at least one selected from the group consisting of source/drain regions, contact pads, contact plugs, and storage electrodes.

3. The method of claim 1, further comprising:
measuring reference critical dimensions for reference conductive structures formed on a reference substrate;
depositing a corona ion charge on the reference conductive structures;
measuring reference surface voltage variations caused by leakage current related to the reference conductive structures; and
obtaining the reference data based on the measured reference critical dimensions and the measured reference surface voltage variations.

4. The method of claim 3, wherein the reference critical dimensions are measured using an image of the reference conductive structures.

5. The method of claim 4, wherein the image is acquired by an electron microscope.

6. The method of claim 3, further comprising:
calculating an average value of the measured reference critical dimensions.

7. The method of claim 1, wherein the corona ion charge is deposited on a predetermined measurement region of the substrate.

8. A method of measuring a critical dimension associated with openings formed in an insulating layer, the method comprising:
depositing a corona ion charge on the insulating layer, wherein the insulating layer is formed on a substrate and exposes conductive structures formed on the substrate;
measuring surface voltage variations caused by leakage current related to the exposed conductive structures; and
comparing the measured surface voltage variations with reference data to determine the critical dimension.

9. The method of claim 8, wherein the conductive structures comprise at least one selected from a group consisting of source/drain regions, contact pads, contact plugs, and storage electrodes.

10. The method of claim 8, further comprising:
measuring reference critical dimensions for reference openings formed in a reference insulating layer exposing reference conductive structures on a reference substrate;
depositing a corona ion charge on the reference insulating layer;
measuring reference surface voltage variations caused by leakage current related to the exposed reference conductive structures; and
obtaining the reference data based on the measured reference critical dimensions and the measured reference surface voltage variations.

11. The method of claim 10, wherein the reference critical dimensions are measured using an image of the reference insulating layer.

12. The method of claim 11, wherein the image is acquired by an electron microscope.

13. The method of claim 10, further comprising:
calculating an average value of the measured reference critical dimensions.

14. The method of claim 8, wherein the corona ion charge is deposited on a predetermined measurement region of the substrate.
